(19) United States
(12) Patent Application Publication
(10) Pub. No.: US 2026/0362884 A1
(43) Pub. Date: Nov. 12, 2026

(54) SEMICONDUCTOR LIGHT-EMITTING DEVICE FOR PIXELS, AND DISPLAY DEVICE COMPRISING SAME

(71) Applicant: LG ELECTRONICS INC., Seoul (KR)

(72) Inventors: Sungjin PARK, Seoul (KR); Sunghyun MOON, Seoul (KR); Jungsub KIM, Seoul (KR); Hwankuk YUH, Seoul (KR)

(73) Assignee: LG ELECTRONICS INC., Seoul (KR)

(21) Appl. No.: 19/487,381

(22) PCT Filed: Jun. 15, 2023
(86) PCT No.: PCT/KR2023/008256

§ 371 Date: Nov. 24, 2025

(51) Int. Cl. H10H 29/49; H10H 29/856

(52) U.S. Cl. CPC H10H 29/49; H10H 29/856

(57) ABSTRACT

A semiconductor light emitting device for pixels according to an embodiment includes a first-first conductivity-type semiconductor layer; a light emitting structure including a first-first conductivity-type semiconductor layer, an active layer, and a second conductivity-type semiconductor layer disposed on the first-first conductivity-type semiconductor layer, and at least one electrode disposed on the first-first conductivity-type semiconductor layer; wherein side surfaces of the first-first conductivity-type semiconductor layer and the light emitting structure may have different inclination directions.

### TECHNICAL FIELD

The embodiment relates to a semiconductor light emitting device for pixels and a display device including the same.

### BACKGROUND ART

Large-area displays include liquid crystal displays (LCDs), organic light emitting diode (OLED) displays, and micro-LED displays.

A micro-LED display uses micro-LEDs, semiconductor light emitting diodes with a diameter or cross-sectional area of 100um or less, as display elements.

Micro-LED displays utilize semiconductor light emitting diodes (micro-LEDs) as display elements, offering superior performance in many characteristics, including contrast ratio, response speed, color reproducibility, viewing angle, brightness, resolution, lifespan, luminous efficiency, and luminance.

In particular, micro-LED displays offer the advantage of modular screen separation and assembly, allowing for flexible size and resolution adjustments and the implementation of flexible displays.

However, large-scale micro-LED displays require millions of micro-LEDs, posing technical problems in quickly and accurately transferring micro-LEDs onto the display panel.

Recently developed transfer technologies include the pick-and-place process, the laser lift-off method, and the self-assembly method.

Among these, the self-assembly method, in which semiconductor light emitting devices autonomously find their assembly positions within a fluid, is advantageous for implementing large-screen display devices.

Recently, U.S. Pat. No. 9,825,202 presented a micro-LED structure suitable for self-assembly. However, research on the technology for manufacturing displays through self-assembly of micro-LEDs remains limited.

In particular, in the case of rapidly transferring millions or more semiconductor light emitting devices to large displays in conventional technology, the transfer speed can be improved, but the transfer error rate can increase, which causes a technical problem of low transfer yield.

Meanwhile, a self-assembly transfer process using dielectrophoresis (DEP) is being attempted in related technologies, but there is a problem of low self-assembly yield due to unevenness of the DEP force.

In addition, there is a problem that the assembly rate and positioning precision are reduced because the inclination of the assembly hole and the inclination of the semiconductor light emitting device are different in opposite directions during the process of self-assembling the semiconductor light emitting device into the assembly hole.

### DISCLOSURE

### Technical Problem

One of the technical objects of the embodiment is to prevent misassembly and defective assembly when assembling semiconductor light emitting devices in a display device.

Another technical object is to improve the assembly rate and positional accuracy during self-assembly of semiconductor light emitting devices.

Another technical object is to improve the light distribution of semiconductor light emitting devices to enhance light efficiency.

Another technical object is to improve the degree of freedom in the design of the size and position of electrodes for electrical connection with contact electrodes in horizontal semiconductor light emitting devices.

Furthermore, one of the technical objects of the embodiment is to ensure the ease of a contact electrode process for electrical connection with a semiconductor light emitting device and to improve the reliability of the contact electrode.

Furthermore, one of the technical objects of the embodiment is to prevent defective assembly, such as color mixing or double assembly, regardless of the semiconductor epitaxial material constituting the semiconductor light emitting device.

The technical objects of the embodiment are not limited to those described in this section and include those that can be understood through the description of the invention.

### Technical Solution

A semiconductor light emitting device for pixels according to an embodiment includes a first-first conductivity-type semiconductor layer; a light emitting structure including a first-second conductivity-type semiconductor layer, an active layer, and a second conductivity-type semiconductor layer disposed on the first-first conductivity-type semiconductor layer, and at least one electrode disposed on the first-first conductivity-type semiconductor layer; wherein side surfaces of the first-first conductivity-type semiconductor layer and the light emitting structure may have different inclination directions.

Furthermore, in the embodiment, the inclination of the side surface of the first-first conductivity-type semiconductor layer and the inclination of the side surface of the light emitting structure may have a positive (+) inclination and a negative (−) inclination, respectively, with respect to the upper surface of the first-first conductivity-type semiconductor layer.

Furthermore, in the embodiment, the angle between the lower surface and the side surface of the first-first conductivity-type semiconductor layer may be an obtuse angle, and the angle between the upper surface and the side surface of the first-first conductivity-type semiconductor layer may be an acute angle.

Furthermore, in the embodiment, the length of the upper surface of the first-first conductivity-type semiconductor layer may be longer than the length of the lower surface.

Furthermore, the embodiment may further include a reflective film disposed on the side surface or the lower surface of the first-first conductivity-type semiconductor layer.

Furthermore, in the embodiment, the light emitting structure may be disposed to one side with respect to the center of the first-first conductivity-type semiconductor layer.

Furthermore, a display device including a semiconductor light emitting device for pixels according to an embodiment includes a substrate; an assembly barrier wall disposed on the substrate and having an assembly hole; and a semiconductor light emitting device disposed in the assembly hole, wherein the semiconductor light emitting device may include the semiconductor light emitting device for pixels according to any one of claims 1 to 6.

Furthermore, in the embodiment, one side surface of the first-first conductivity-type semiconductor layer and the assembly barrier wall facing each other may have a corresponding slope.

Furthermore, in the embodiment, the distance between the lower end of the first-first conductivity-type semiconductor layer and the assembly barrier may correspond to the distance between the lower end of the first-first conductivity-type semiconductor layer and the assembly barrier.

Furthermore, in the embodiment, the facing sides of the first-first conductivity-type semiconductor layer and the assembly barrier may have parallel slopes.

Furthermore, in the embodiment, the distance between the lower end of the first-first conductivity-type semiconductor layer and the assembly barrier may be equal to the distance between the lower end of the first-first conductivity-type semiconductor layer and the assembly barrier.

### Advantageous Effects

The semiconductor light emitting device for pixels according to the embodiment and the display device including the same have a technical effect of improving the correct assembly rate during self-assembly.

For example, the embodiment can prevent defective assembly such as double assembly or non-assembly and improve the correct assembly rate by forming the slopes of one side where the first-first conductivity-type semiconductor layer and the assembly barrier face each other correspondingly.

Furthermore, the embodiment has a technical effect that can improve the degree of freedom in designing the size and position of electrodes for electrical connection with contact electrodes in a horizontal semiconductor light emitting device.

For example, in the embodiment, since the side surfaces of the light emitting structure and the first-first conductivity-type semiconductor layer are formed in different inclination directions, the upper surface of the first-first conductivity-type semiconductor layer is longer than the lower surface, and the degree of freedom in designing the size and position of the electrodes located on the upper surface can be improved.

Furthermore, the embodiment has the technical effect of ensuring the ease of the contact electrode process for electrical connection with a semiconductor light emitting device and improving the reliability of the contact electrode.

For example, the embodiment can secure the area of the upper surface of the first-first conductivity-type semiconductor layer in a semiconductor light emitting device having a heterogeneous slope structure, thereby sufficiently securing the electrode area, improving the error in the contact electrode process, and enhancing reliability.

Furthermore, the embodiment has the technical effect of improving the light distribution of a semiconductor light emitting device and thus enhancing light efficiency.

Furthermore, the embodiment has a technical effect of improving light extraction at the center of a semiconductor light emitting device, thereby improving deviation according to the optical viewing angle.

For example, the embodiment can improve light distribution through a heterogeneous slope structure in a semiconductor light emitting device, and can improve light extraction efficiency in the upward direction by disposing a reflective film on the side and bottom of the first-first conductivity-type semiconductor layer.

Furthermore, the embodiment has a technical effect of preventing defective assembly, such as color mixing or double assembly, by designing the gap between the chip and the barrier wall to be consistent regardless of the semiconductor epitaxial material constituting the semiconductor light emitting device.

For example, the embodiment can prevent color mixing and double assembly by ensuring that the gap between the chip and the barrier wall corresponds even when the semiconductor epitaxial material constituting the semiconductor light emitting device is different, thereby preventing a decrease in the assembly rate.

The technical effects of the embodiment are not limited to those described in this section, but include those that can be understood through the description of the invention.

### DESCRIPTION OF DRAWINGS

FIG. 1 is an exemplary diagram illustrating a living room of a house in which a display device according to an embodiment is disposed.

FIG. 2 is a block diagram schematically illustrating a display device according to an embodiment.

FIG. 3 is a circuit diagram illustrating an embodiment of a pixel of FIG. 2.

FIG. 4 is an enlarged view of the first panel area of the display device of FIG. 1.

FIG. 5 is a cross-sectional view taken along line B1-B2 of area A2 of FIG. 4.

FIG. 6 is an exemplary diagram illustrating a light emitting device according to an embodiment assembled onto a substrate using a self-assembly method.

FIGS. 7a and 7b are conceptual diagrams of a display device in which a semiconductor light emitting device is internally assembled.

FIG. 8 is a cross-sectional view of a semiconductor light emitting device for pixels according to a first embodiment.

FIG. 9 is a cross-sectional view of a semiconductor light emitting device for pixels according to a second embodiment.

FIG. 10 is a conceptual diagram of a display device including a semiconductor light emitting device for pixels according to a third embodiment.

FIG. 11 is a conceptual diagram of a semiconductor light emitting device for pixels according to a fourth embodiment.

FIG. 12 is a conceptual diagram of a display device including a semiconductor light emitting device for pixels according to a fifth embodiment.

### MODE FOR INVENTION

Hereinafter, the embodiments disclosed in the present specification will be described in detail with reference to the attached drawings. The suffixes ‘module’ and ‘part’ used for components in the following description are given or used interchangeably in consideration of the ease of writing the specification, and do not have distinct meanings or roles in themselves. In addition, the attached drawings are provided to facilitate easy understanding of the embodiments disclosed in the present specification, and the technical ideas disclosed in the present specification are not limited by the attached drawings. In addition, when an element such as a layer, area, or substrate is referred to as existing ‘on’ another element, this includes that it may be directly on the other element, or that other intermediate elements may exist therebetween.

The display devices described herein may include digital TVs, mobile phones, smart phones, laptop computers, digital broadcasting terminals, personal digital assistants (PDAs), portable multimedia players (PMPs), navigation systems, slate PCs, tablet PCs, Ultrabooks, desktop computers, and the like. However, the configurations according to the embodiments described herein may also be applied to devices capable of displaying, even if they are new product types developed in the future.

The following describes a light emitting device according to an embodiment and a display device including the same.

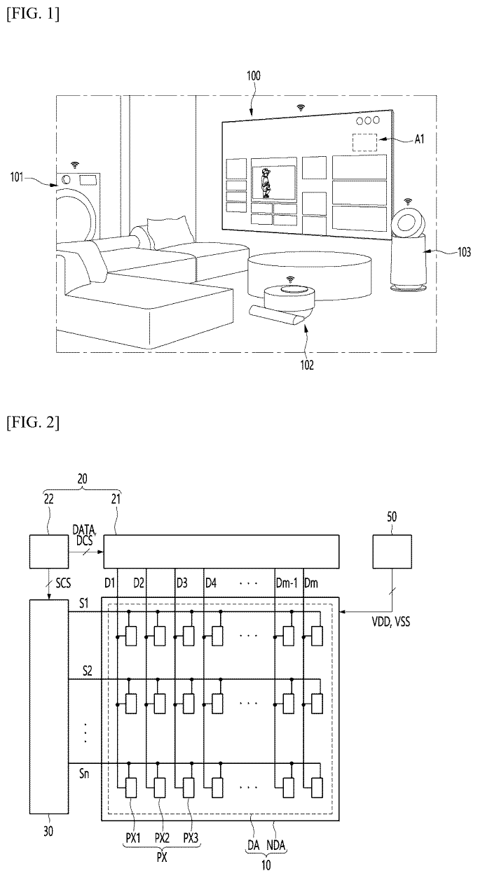

FIG. 1 illustrates a living room of a house in which a display device 100 according to an embodiment is placed.

The display device 100 according to the embodiment may display the status of various electronic products such as a washing machine 101, a robot vacuum cleaner 102, and an air purifier 103, and may communicate with each electronic product based on IoT and control each electronic product based on user setting data.

The display device 100 according to the embodiment may include a flexible display manufactured on a thin and flexible substrate. The flexible display may be bent or rolled like paper while maintaining the characteristics of a conventional flat panel display.

In a flexible display, visual information may be realized by independently controlling the light emission of unit pixels disposed in a matrix. A unit pixel is the smallest unit for expressing a single color. The unit pixels of a flexible display may be realized by light emitting devices. In an exemplary embodiment, the light emitting devices may be Micro-LEDs or Nano-LEDs, but are not limited thereto.

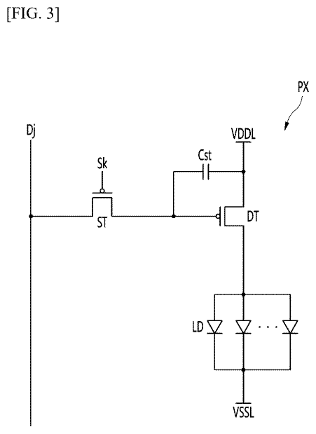

FIG. 2 is a block diagram schematically illustrating a display device according to an exemplary embodiment, and FIG. 3 is a circuit diagram illustrating an embodiment of the pixels of FIG. 2.

Referring to FIGS. 2 and 3, a display device according to an exemplary embodiment may include a display panel 10, a driving circuit 20, a scan driving unit 30, and a power supply circuit 50.

The display device 100 of the embodiment may drive the light emitting device using an active matrix (AM) method or a passive matrix (PM) method.

The driving circuit 20 may include a data driving unit 21 and a timing control unit 22.

The display panel 10 may be divided into a display area (DA) and a non-display area (NDA) disposed around the display area (DA). The display area (DA) is an area where pixels (PX) are formed to display an image. The display panel 10 may include data lines (D1 to Dm, m is an integer greater than or equal to 2), scan lines (S1 to Sn, n is an integer greater than or equal to 2) intersecting the data lines (D1 to Dm), a high-potential voltage line to which a high-potential voltage is supplied, a low-potential voltage line to which a low-potential voltage is supplied, and pixels (PX) connected to the data lines (D1 to Dm) and the scan lines (S1 to Sn).

Each of the pixels (PX) may include a first sub-pixel (PX1), a second sub-pixel (PX2), and a third sub-pixel (PX3). The first sub-pixel (PX1) may emit a first color light of a first wavelength, the second sub-pixel (PX2) may emit a second color light of a second wavelength, and the third sub-pixel (PX3) may emit a third color light of a third wavelength. The first color light may be red light, the second color light may be green light, and the third color light may be blue light, but the present invention is not limited thereto. In addition, although FIG. 2 illustrates that each of the pixels (PX) includes three sub-pixels, the present invention is not limited thereto. That is, each of the pixels (PX) may include four or more sub-pixels.

Each of the first sub-pixel (PX1), the second sub-pixel (PX2), and the third sub-pixel (PX3) may be connected to at least one of the data lines (D1 to Dm), at least one of the scan lines (S1 to Sn), and a high-potential voltage line. The first sub-pixel (PX1) may include light emitting devices (LD), a plurality of transistors for supplying current to the light emitting devices (LD), and at least one capacitor (Cst), as shown in FIG. 3.

Although not illustrated in the drawing, each of the first sub-pixel (PX1), the second sub-pixel (PX2), and the third sub-pixel (PX3) may include only one light emitting device (LD) and at least one capacitor (Cst).

Each of the light emitting devices (LD) may be a semiconductor light emitting diode including a first electrode, a plurality of conductivity-type semiconductor layers, and a second electrode. Here, the first electrode may be an anode electrode, and the second electrode may be a cathode electrode, but this is not limited thereto.

Referring to FIG. 3, the plurality of transistors may include a driving transistor (DT) that supplies current to light emitting devices (LD), and a scan transistor (ST) that supplies a data voltage to a gate electrode of the driving transistor (DT). The driving transistor (DT) may include a gate electrode connected to a source electrode of the scan transistor (ST), a source electrode connected to a high-potential voltage line to which a high-potential voltage is applied, and a drain electrode connected to first electrodes of the light emitting devices (LD). The scan transistor (ST) may include a gate electrode connected to a scan line (Sk, where k is an integer satisfying 1≤k≤n), a source electrode connected to the gate electrode of the driving transistor (DT), and a drain electrode connected to a data line (Dj, where j is an integer satisfying 1≤j≤m).

A capacitor (Cst) is formed between the gate electrode and the source electrode of the driving transistor (DT). The storage capacitor (Cst) may charge the difference between the gate voltage and the source voltage of the driving transistor (DT).

The driving transistor (DT) and the scan transistor (ST) may be formed as thin film transistors. Furthermore, although FIG. 3 illustrates the case where the driving transistor (DT) and the scan transistor (ST) are formed as P-type MOSFETs (Metal Oxide Semiconductor Field Effect Transistors), the present invention is not limited thereto. The driving transistor (DT) and the scan transistor (ST) may also be formed as N-type MOSFETs. In this case, the positions of the source electrodes and the drain electrodes of each of the driving transistor (DT) and the scan transistor (ST) may be changed.

In addition, in FIG. 3, it is exemplified that each of the first sub-pixel (PX1), the second sub-pixel (PX2), and the third sub-pixel (PX3) includes a 2T1C (2 Transistor 1 capacitor) having one driving transistor (DT), one scan transistor (ST), and one capacitor (Cst), but the present invention is not limited thereto. Each of the first sub-pixel (PX1), the second sub-pixel (PX2), and the third sub-pixel (PX3) may include a plurality of scan transistors (ST) and a plurality of capacitors (Cst).

Referring again to FIG. 2, the driving circuit 20 outputs signals and voltages for driving the display panel 10. For this purpose, the driving circuit 20 may include a data driving unit 21 and a timing control unit 22.

The data driving unit 21 receives digital video data (DATA) and a source control signal (DCS) from the timing control unit 22. The data driving unit 21 converts the digital video data (DATA) into analog data voltages according to the source control signal (DCS) and supplies the converted data to the data lines (D1 to Dm) of the display panel 10.

The timing control unit 22 receives digital video data (DATA) and timing signals from the host system. The timing signals may include a vertical sync signal, a horizontal sync signal, a data enable signal, and a dot clock. The host system may be an application processor of a smartphone or tablet PC, a monitor, a system-on-chip of a TV, etc.

The scan driving unit 30 receives a scan control signal (SCS) from the timing control unit 22. The scan driving unit 30 generates scan signals according to the scan control signal (SCS) and supplies them to the scan lines (S1 to Sn) of the display panel 10. The scan driving unit 30 may include a plurality of transistors and may be formed in a non-display area (NDA) of the display panel 10. Alternatively, the scan driving unit 30 may be formed as an integrated circuit, in which case it may be mounted on a gate flexible film attached to the other side of the display panel 10.

The power supply circuit 50 may generate a high-potential voltage (VDD) and a low-potential voltage (VSS) for driving the light emitting devices (LD) of the display panel 10 from the main power supply and supply them to the high-potential voltage line and the low-potential voltage line of the display panel 10. In addition, the power supply circuit 50 may generate and supply driving voltages for driving the driving circuit 20 and the scan driving unit 30 from the main power supply.

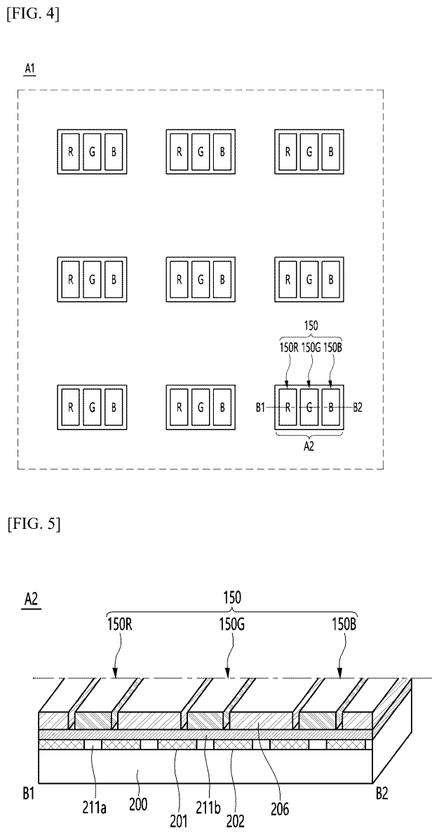

FIG. 4 is an enlarged view of the first panel area (A1) of the display device of FIG. 1.

According to FIG. 4, the display device 100 of the embodiment may be manufactured by mechanically and electrically connecting multiple panel areas, such as the first panel area (A1), through tiling.

The first panel area (A1) may include multiple light emitting devices 150 disposed for each unit pixel (PX of FIG. 2).

For example, the unit pixel (PX) may include a first sub-pixel (PX1), a second sub-pixel (PX2), and a third sub-pixel (PX3). For example, multiple red light emitting devices 150R may be disposed in the first sub-pixel (PX1), multiple green light emitting devices 150G may be disposed in the second sub-pixel (PX2), and multiple blue light emitting devices 150B may be disposed in the third sub-pixel (PX3). The unit pixel (PX) may further include a fourth sub-pixel in which no light emitting devices are disposed, but this is not limited thereto. Meanwhile, the light emitting device 150 may be a semiconductor light emitting device.

Next, FIG. 5 is a cross-sectional view taken along line B1-B2 of area A2 of FIG. 4.

Referring to FIG. 5, the display device 100 of the embodiment may include a substrate 200, assembly wiring 201, 202, a first insulating layer 211a, a second insulating layer 211b, a third insulating layer 206, and a plurality of light emitting devices 150.

The assembly wiring may include a first assembly wiring 201 and a second assembly wiring 202 that are spaced apart from each other. The first assembly wiring 201 and the second assembly wiring 202 may be provided to generate a dielectrophoretic force for assembling the light emitting device 150. In addition, the first assembly wiring 201 and the second assembly wiring 202 may be electrically connected to the electrodes of the light emitting device and function as electrodes of the display panel.

The assembly wiring 201, 202 may be formed of a light-transmitting electrode (ITO) or may include a metal material with excellent electrical conductivity. For example, the assembly wiring 201, 202 may be formed of at least one of titanium (Ti), chromium (Cr), nickel (Ni), aluminum (Al), platinum (Pt), gold (Au), tungsten (W), and molybdenum (Mo), or an alloy thereof.

A first insulating layer 211a may be disposed between the first assembly wiring 201 and the second assembly wiring 202, and a second insulating layer 211b may be disposed on the first assembly wiring 201 and the second assembly wiring 202. The first insulating layer 211a and the second insulating layer 211b may be an oxide film, a nitride film, or the like, but are not limited thereto.

The light emitting device 150 may include a red light emitting device 150, a green light emitting device 150G, and a blue light emitting device 150B0 to form a unit pixel (sub-pixel), but is not limited thereto, and may include a red phosphor and a green phosphor to implement red and green, respectively.

The substrate 200 may be formed of glass or polyimide. In addition, the substrate 200 may include a flexible material such as PEN (Polyethylene Naphthalate) or PET (Polyethylene Terephthalate). In addition, the substrate 200 may be a light-transmitting material, but is not limited thereto.

The third insulating layer 206 may include an insulating and flexible material such as polyimide, PEN, PET, etc., and may be formed integrally with the substrate 200 to form a single substrate.

The third insulating layer 206 may be a conductive adhesive layer having adhesive and conductive properties, and the conductive adhesive layer may be flexible to enable a flexible function of the display device. For example, the third insulating layer 206 may be a conductive adhesive layer such as an anisotropic conductive film (ACF) or an anisotropic conductive medium, a solution containing conductive particles, etc. The conductive adhesive layer may be a layer that is electrically conductive in a direction vertical to the thickness, but electrically insulating in a direction horizontal to the thickness.

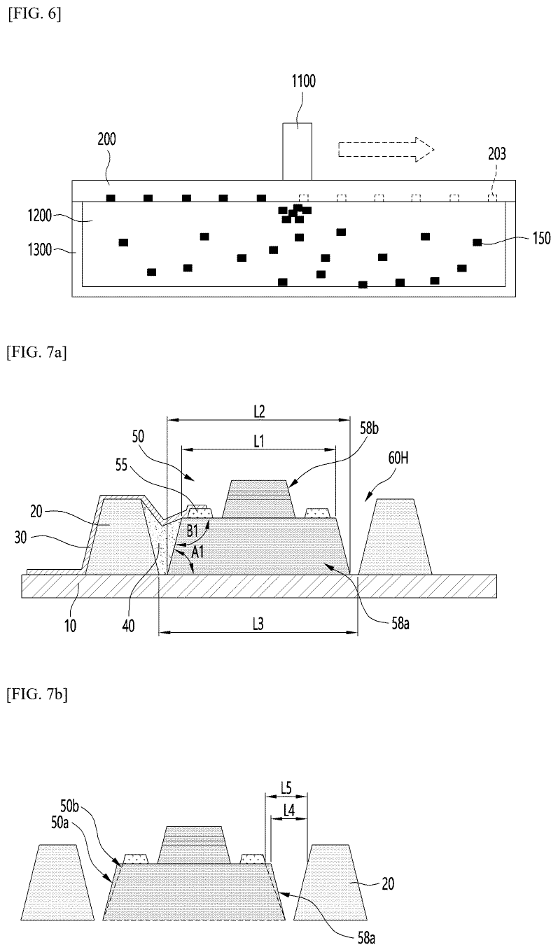

The third insulating layer 206 may include an assembly hole 203 into which the light emitting device 150 is inserted (see FIG. 6). Therefore, during self-assembly, the light emitting device 150 may be easily inserted into the assembly hole 203 of the third insulating layer 206. The assembly hole 203 may be referred to as an insertion hole, a fixing hole, an alignment hole, etc.

The spacing between the assembly wirings 201, 202 is formed to be smaller than the width of the light emitting device 150 and the width of the assembly hole 203, thereby enabling the assembly position of the light emitting device 150 to be more precisely fixed using an electric field.

A third insulating layer 206 is formed on the assembly wiring 201, 202 to protect the assembly wiring 201, 202 from the fluid 1200 and prevent leakage of current flowing in the assembly wiring 201, 202. The third insulating layer 206 may be formed as a single layer or multiple layers of an inorganic insulator such as silica or alumina or an organic insulator.

In addition, the third insulating layer 206 may include an insulating and flexible material, such as polyimide, PEN, or PET, and may be formed integrally with the substrate 200 to form a single substrate.

The third insulating layer 206 may be an adhesive insulating layer or a conductive adhesive layer. The third insulating layer 206 may be flexible, thereby enabling a flexible function of the display device.

The third insulating layer 206 may have a barrier wall, and an assembly hole 203 may be formed by the barrier wall. For example, when forming the substrate 200, a portion of the third insulating layer 206 may be removed, allowing each of the light emitting devices 150 to be assembled into the assembly hole 203 of the third insulating layer 206.

An assembly hole 203 is formed in the substrate 200 to which light emitting devices 150 are coupled, and the surface where the assembly hole 203 is formed may come into contact with a fluid 1200. The assembly hole 203 may guide the precise assembly position of the light emitting device 150.

Meanwhile, the assembly hole 203 may have a shape and size corresponding to the shape of the light emitting device 150 to be assembled at the corresponding position. Accordingly, it is possible to prevent another light emitting device from being assembled in the assembly hole 203 or multiple light emitting devices from being assembled.

FIG. 6 is a drawing showing an embodiment of a light emitting device according to an embodiment being assembled on a substrate by a self-assembly method, and the self-assembly method of the light emitting device will be described with reference to the drawings.

The substrate 200 may be a panel substrate of a display device. In the following description, the substrate 200 is described as a panel substrate of a display device, but the embodiment is not limited thereto.

Referring to FIG. 6, a plurality of light emitting devices 150 may be placed in a chamber 1300 filled with a fluid 1200. The fluid 1200 may be, but is not limited to, ultrapure water. The chamber may be referred to as a tank, a container, a vessel, etc.

Thereafter, a substrate 200 may be placed on the chamber 1300. Depending on the embodiment, the substrate 200 may be placed into the chamber 1300.

As illustrated in FIG. 5, a pair of assembly wirings 201, 202 corresponding to each light emitting device 150 to be assembled may be placed on the substrate 200.

Referring to FIG. 6, after the substrate 200 is placed, an assembly device 1100 including a magnetic body may move along the substrate 200. For example, a magnet or an electromagnet may be used as the magnetic body. The assembly device 1100 may move in contact with the substrate 200 to maximize the area affected by the magnetic field within the fluid 1200. Depending on the embodiment, the assembly device 1100 may include a plurality of magnetic bodies or may include magnetic bodies of a size corresponding to the substrate 200. In this case, the movement distance of the assembly device 1100 may be limited within a predetermined range.

Due to the magnetic field generated by the assembly device 1100, the light emitting device 150 within the chamber 1300 may move toward the assembly device 1100.

The light emitting device 150 may move toward the assembly device 1100 and enter the assembly hole 203 by the dielectric electrophoretic force (DEP force) to come into contact with the substrate 200.

Specifically, the assembly wiring 201, 202 forms an electric field by an externally supplied power source, and a dielectrophoretic force may be formed between the assembly wiring 201, 202 by this electric field. The light emitting device 150 may be fixed to the assembly hole 203 on the substrate 200 by this dielectrophoretic force.

The light emitting device 150 in contact with the substrate 200 may be prevented from being detached by the movement of the assembly device 1100 by the electric field applied by the assembly wiring 201, 202 formed on the substrate 200. According to an embodiment, the time required for each of the light emitting devices 150 to be assembled on the substrate 200 may be drastically shortened by the self-assembly method using the electromagnetic field described above, and thus, a large-area, high-pixel display may be implemented more quickly and economically.

At this time, a predetermined solder layer (not shown) may be formed between the light emitting device 150 assembled on the assembly hole 203 of the substrate 200 and the assembly electrode, thereby improving the bonding strength of the light emitting device 150.

Next, a molding layer (not shown) may be formed on the assembly hole 203 of the substrate 200. The molding layer may be a light-transmitting resin or a resin containing a reflective material or a scattering material.

FIGS. 7a and 7b are conceptual diagrams of a display device in which a semiconductor light emitting device being studied is assembled internally.

Referring to FIG. 7a, the semiconductor light emitting device 50 may include a first-first conductivity-type semiconductor layer 58a and a light emitting structure 58b. When forming a semiconductor light emitting device 50, the first-first conductivity-type semiconductor layer 58a and the light emitting structure 58b may have inclinations in the same direction by mesa etching. In detail, the side surfaces of the first-first conductivity-type semiconductor layer 58a and the light emitting structure 58b may have inclinations in the same direction with respect to the vertical. In addition, the angle (A1) between the lower surface and the side surface of the first-first conductivity-type semiconductor layer 58a may be an acute angle, and the angle (B1) between the upper surface and the side surface of the first-first conductivity-type semiconductor layer 58a may be an obtuse angle. In addition, due to the inclination of the first-first conductivity-type semiconductor layer 58a, the length (L1) of the upper surface of the first-first conductivity-type semiconductor layer 58a may be shorter than the length (L2) of the lower surface. A barrier wall 20 having an assembly hole (60H) may be disposed on the substrate 10. The distance (L3) between the barrier walls 20 may be greater than the maximum width of the semiconductor light emitting device 50.

Meanwhile, during self-assembly, the semiconductor light emitting device 50 may be assembled on the substrate 10 so that the lower surface of the first-first conductivity-type semiconductor layer 58a is in contact with the substrate. However, since the side slope of the assembly hole (60H) or the barrier wall 20 has an inclination opposite to the side slope of the semiconductor light emitting device 50, the distance between the upper end of the first-first conductivity-type semiconductor layer 58a and the barrier wall 20 becomes smaller than the distance between the lower end of the first-first conductivity-type semiconductor layer 58a and the barrier wall 20.

Accordingly, when the semiconductor light emitting device 50 is assembled within the assembly hole (60H), there is a problem in that the assembly rate and positional accuracy are reduced due to a small allowance. In addition, since the lower length (L2) of the first-first conductivity-type semiconductor layer 58a that first enters the assembly hole (60H) is longer than the upper length (L1), there is a problem that a part of the lower part may collide with the barrier wall 20 and result in non-assembly or defective assembly.

Meanwhile, when a semiconductor light emitting device is assembled in an assembly hole, the length of the lower surface of the semiconductor light emitting device should be shorter than the length of the lower surface of the assembly hole. However, since the length (L1) of the upper surface of the first-first conductivity-type semiconductor layer 58a is shorter than the length (L2) of the lower surface, the size of the semiconductor light emitting device 50 is formed small, and there is a problem that the size and position of the electrodes are also restricted in the design.

In addition, during the process of electrically connecting the semiconductor light emitting device to the display panel, the distance between the barrier wall 20 and the upper surface of the first-first conductivity-type semiconductor layer 58a is long and the gap is large, so the insulating layer 40 formed in the gap is formed unevenly, and the contact electrode 30 connected to the first electrode 55 along the insulating layer 40 may be positioned unstably. Additionally, the distance between the barrier wall 20 and the first electrode 55 increases, increasing the length of the contact electrode 30, which may lower the reliability of the electrode. Accordingly, the reliability of the contact electrode 30 may decrease, or issues may arise in the electrical connection, resulting in problems such as defective lighting.

Referring to FIG. 7b, the semiconductor light emitting devices emitting R, G, and B colors may each have different lateral slopes of their first-first conductivity-type semiconductor layers 58a. Specifically, the semiconductor light emitting devices 50a emitting green and blue colors may use the same epitaxial material composition and thus undergo the same mesa etching process, resulting in the same slopes of their first-first conductivity-type semiconductor layers 58a.

On the other hand, the semiconductor light emitting device 50b emitting red color may use a different epitaxial material composition than the green and blue colors, resulting in different lateral slopes of its first-first conductivity-type semiconductor layers 58. Since the semiconductor light emitting devices (50a, 50b) assembled in the same assembly hole have different slopes, their spacing from the barrier walls 20 differs, which may hinder proper assembly and lead to defects such as color mixing and double assembly.

Below, an embodiment for solving the above problem will be described.

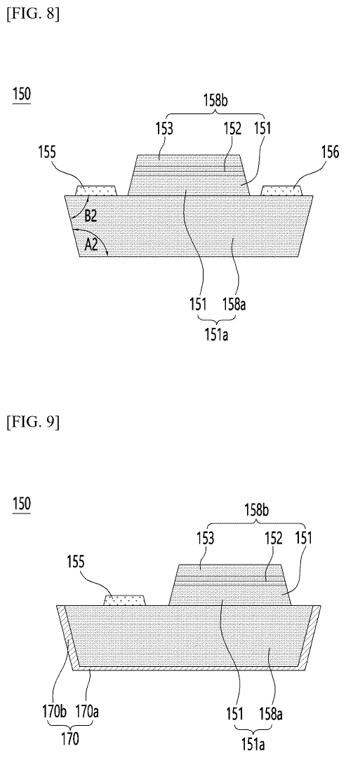

FIG. 8 is a cross-sectional view of a semiconductor light emitting device for pixels according to a first embodiment. Referring to FIG. 8, the semiconductor light emitting device for pixels 150 of the first embodiment may include a first-first conductivity-type semiconductor layer 151a and a light emitting structure 158b. The first-first conductivity-type semiconductor layer 151a may include a first-first conductivity-type semiconductor layer 158a and a first-second conductivity-type semiconductor layer 151. In addition, the light emitting structure 158b may include the first-second conductivity-type semiconductor layer 151, an active layer 152, and a second conductivity-type semiconductor layer 153.

In addition, at least one electrode 155 may be disposed on the first-first conductivity-type semiconductor layer 158a. The electrode 155 may be connected to a contact electrode after a panel process to supply an electrical signal to the semiconductor light emitting device.

The semiconductor light emitting device 150 may be a horizontal semiconductor, but is not limited thereto.

The first conductivity-type semiconductor layer 151a may be an n-type semiconductor layer, and the second conductivity-type semiconductor layer 153 may be a p-type semiconductor layer, but is not limited thereto. The first conductivity-type semiconductor layer 151a, the active layer 152, and the second conductivity-type semiconductor layer 153 may be formed of a compound semiconductor material. For example, the compound semiconductor material may be a group III-V compound semiconductor material, a group II-VI compound material, etc. For example, the compound semiconductor may be a binary compound selected from the group consisting of GaP, GaAs, GaSb, AlP, AlAs, AlSb, InP, InAs, InSb, or mixtures thereof; A ternary compound selected from the group consisting of GaNP, GaNAs, GaNSb, GaPAs, GaPSb, AlInP, AINP, AlNAs, AlNSb, AlPAs, AlPSb, InNP, InNAs, InNSb, InPAs, InPSb, GaAlNP or mixtures thereof; and a quaternary compound selected from the group consisting of AlGaInP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb or mixtures thereof.

For example, the first conductivity-type semiconductor layer 151a may include a first conductive dopant, and the second conductivity-type semiconductor layer 153 may include a second conductive dopant. For example, the first conductive dopant may be an n-type dopant, such as silicon (Si), and the second conductive dopant may be a p-type dopant, such as boron (B).

The active layer 152 is a region that generates light and may generate light having a specific wavelength band depending on the material properties of the compound semiconductor. In addition, the active layer may have a multiple quantum well or single quantum well structure, and the wavelength band may be determined by the energy bandgap of the compound semiconductor included in the active layer. Therefore, the semiconductor light emitting device of the embodiment may generate UV light, blue light, green light, and red light depending on the energy bandgap of the compound semiconductor included in the active layer.

Meanwhile, the semiconductor light emitting device 150 may include a first-first conductivity-type semiconductor layer 158a and a light emitting structure 158b disposed on the first-first conductivity-type semiconductor layer 158a. The side slope of the first-first conductivity-type semiconductor layer 158a may have different directions relative to the vertical side slope of the light emitting structure 158b.

Specifically, the angle (A2) between the lower surface and the side surface of the first-first conductivity-type semiconductor layer 158a may be an obtuse angle, and the angle (B2) between the upper surface and the side surface of the first-first conductivity-type semiconductor layer 158a may be an acute angle. The length of the upper surface of the first-first conductivity-type semiconductor layer 158a may be greater than the length of the lower surface.

In addition, in the case of the light emitting structure 158b, the angle between the lower surface and the side surface may be an acute angle, and the angle between the upper surface and the side surface may be an obtuse angle. In addition, the length of the lower surface of the light emitting structure 158b may be greater than the length of the upper surface.

Therefore, in the semiconductor light emitting device for pixels according to the first embodiment, the side surfaces of the first-first conductivity-type semiconductor layer and the light emitting structure may have different inclinations relative to the vertical. Specifically, the side surfaces of the first-first conductivity-type semiconductor layer 158a and the light emitting structure 158b may have negative and positive inclinations, respectively, relative to the vertical. In addition, the inclination of the side surface of the first-first conductivity-type semiconductor layer 158a and the inclination of the side surface of the light emitting structure 158b may have positive (+) and negative (−) inclinations, respectively, relative to the upper surface of the first-first conductivity-type semiconductor layer 158a.

In addition, the upper surface of the first-first conductivity-type semiconductor layer 158a may be a polygonal shape including, but not limited to, a circle, an ellipse, and a square.

FIG. 9 is a cross-sectional view of a semiconductor light emitting device for pixels according to a second embodiment. Referring to FIG. 9, the second embodiment may employ the technical features of the first embodiment. For example, the upper surface of the first-first conductivity-type semiconductor layer 158a may have a greater length than the lower surface, and the inclinations of the second mesa and the side surfaces of the first-first conductivity-type semiconductor layer may be in opposite directions relative to the vertical. Next, the technical features of the second embodiment will be described.

Referring to FIG. 9, the semiconductor light emitting device for pixels 150a of the second embodiment may include a first-first conductivity-type semiconductor layer 158a and a light emitting structure 158b. In this case, the light emitting structure 158b may be disposed offset from the center of the first-first conductivity-type semiconductor layer 158b.

In addition, a first reflective film 170a may be disposed on the lower surface of the first-first conductivity-type semiconductor layer 158a. The first reflective film 170a may reflect light directed toward the lower portion of the chip upward, thereby minimizing light loss and improving light efficiency.

In addition, a second reflective film 170b may be disposed on the side surface of the first-first conductivity-type semiconductor layer 158a. The second reflective film 170b may reflect light directed toward the side surface of the chip upward, thereby minimizing light loss and improving light efficiency. The slope of the second reflective film 170b may correspond to the side surface slope of the first-first conductivity-type semiconductor layer 158a.

In the second embodiment, at least one of the first reflective film 170a and the second reflective film 170b may be disposed. When the reflective film 170 is disposed on both the lower surface and the side surface of the first-first conductivity-type semiconductor layer 158a, light distribution is improved, thereby providing the technical effect of further enhancing light efficiency. In addition, there is the technical effect of improving the light extraction efficiency toward the center of the semiconductor light emitting device 150, thereby improving deviation according to the optical viewing angle.

Furthermore, when a reflective film 170 is formed on the first-first conductivity-type semiconductor layer 158, the display panel substrate eliminates the need for a reflective film, thereby simplifying the design. Furthermore, although not illustrated in FIG. 9, an assembly metal for self-assembly may be placed under the semiconductor light emitting device 150.

Therefore, the second embodiment has the technical effect of improving light distribution through a heterogeneous slope structure in the semiconductor light emitting device and further enhancing upward light extraction efficiency by placing a reflective film on the side and underside of the first-first conductivity-type semiconductor layer.

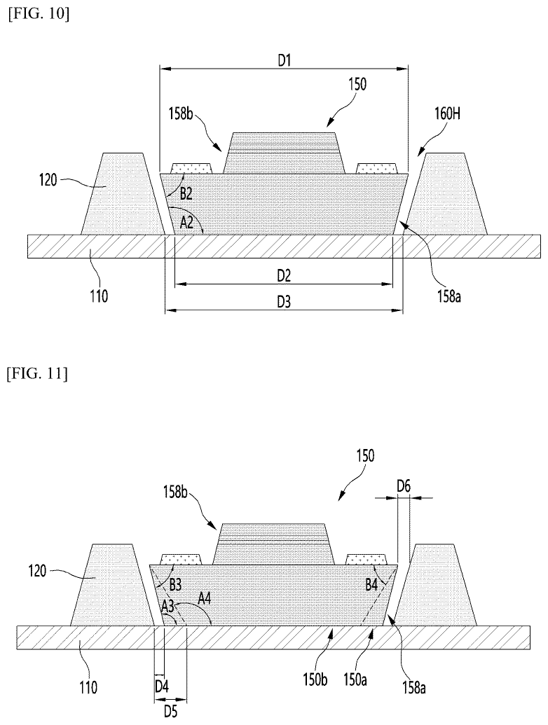

FIG. 10 is a conceptual diagram of a display device including a semiconductor light emitting device according to a third embodiment. In the third embodiment, the semiconductor light emitting device may include the semiconductor light emitting device for pixels of the first and second embodiments.

Referring to FIG. 10, a semiconductor light emitting device 150 may be assembled on a substrate 110. Although not illustrated in FIG. 10, the substrate 110 may include a thin film transistor, an insulating layer, an assembly electrode, an adhesive layer, etc.

A barrier wall 120 may be disposed spaced apart from each other on the substrate 110. The barrier walls 120 may be spaced apart from each other to have a minimum distance of D3. In addition, the barrier wall 120 may have an assembly hole 160H. The length of the lower surface of the assembly hole 160H may be D3. A semiconductor light emitting device 150 may be disposed within the assembly hole 160H.

The semiconductor light emitting device 150 may include a first-first conductivity-type semiconductor layer 158a and a light emitting structure 158b. At this time, the length (D1) of the upper surface of the first-first conductivity-type semiconductor layer 158a may be longer than the length (D2) of the lower surface. In addition, the length (D2) of the lower surface of the first-first conductivity-type semiconductor layer 158a may be shorter than the shortest distance (D3) between the barrier walls. In addition, the length (D1) of the upper surface of the first-first conductivity-type semiconductor layer 158a may be longer than the shortest distance (D3) between the barrier walls.

In addition, the slope of the side surface of the first-first conductivity-type semiconductor layer 158a and the slope of the side surface of the light emitting structure 158b may have a positive (+) slope and a negative (−) slope, respectively, based on the upper surface of the first-first conductivity-type semiconductor layer 158a.

In addition, the slope of the side surface of the first-first conductivity-type semiconductor layer 158a may have the same direction as the slope of the side surface of the barrier wall 120 with respect to the vertical. The slope of the side surface of the first-first conductivity-type semiconductor layer 158a may correspond to the slope of the facing surface of the barrier wall 120. In addition, the gap between the first-first conductivity-type semiconductor layer 158a and the inner wall of the assembly hole 160H may have a predetermined distance. The gap between the lower surface of the first-first conductivity-type semiconductor layer 158a and the barrier wall 120 may correspond to the gap between the upper surface of the first-first conductivity-type semiconductor layer 158a and the barrier wall 120. In addition, the facing side surfaces of the barrier wall 120 and the first-first conductivity-type semiconductor layer 158a may be parallel to each other.

Meanwhile, for assembly, the length (D3) of the lower surface of the semiconductor light emitting device 150 may be smaller than the length of the lower surface of the assembly hole 160H. On the other hand, the first-first conductivity-type semiconductor layer 158a of the semiconductor light emitting device 150 may have the same directionality as the inclination of the assembly hole 160H.

Accordingly, the third embodiment may minimize the gap between the semiconductor light emitting device 150 and the assembly barrier 120.

In addition, the length (D1) of the upper surface of the first-first conductivity-type semiconductor layer 158a may be greater than the length (D2) of the lower surface. Accordingly, the third embodiment has the technical effect of improving the degree of design freedom, such as the size and position of the electrode, within the assembly hole 160H of the semiconductor light emitting device 150.

In addition, the third embodiment has the special technical effect of preventing assembly defects such as under-assembly and double-assembly, improving the assembly rate, and enhancing the precision of the assembly position, since the inclination of the side surface of the first-first conductivity-type semiconductor layer and the light emitting structure have a positive (+) inclination and a negative (−) inclination, respectively, with respect to the upper surface of the first-first conductivity-type semiconductor layer, and the inclination of the first-first conductivity-type semiconductor layer has the same direction as the inclination of the inner wall of the assembly hole.

FIG. 11 is a conceptual diagram of a display device including a semiconductor light emitting device for pixels according to a fourth embodiment. The fourth embodiment may employ the technical features of the third embodiment. For example, the fourth embodiment has the technical effect of improving the assembly rate and positional accuracy during assembly, as the inclination directions of the first-first conductivity-type semiconductor layer and the light emitting structure are different, and the side inclination of the first-first conductivity-type semiconductor layer is in the same direction as the inclination of the inner wall of the assembly hole.

Referring to FIG. 11, the semiconductor light emitting device 150 may be a semiconductor light emitting device that emits red, green, or blue colors. For example, a semiconductor light emitting device that emits green or blue colors may be 150a, and a semiconductor light emitting device that emits red colors may be 150b, but the present invention is not limited thereto.

Meanwhile, in the case of a semiconductor light emitting device 150a emitting green or blue light, the etching process may be identical because a semiconductor epitaxial material of the same composition is used. Accordingly, the slope of the first-first conductivity-type semiconductor layer of the green or blue semiconductor light emitting device 150a may correspond.

On the other hand, in the case of a semiconductor light emitting device 150b emitting red light, the etching process may be different from that of the green or blue semiconductor light emitting device because a semiconductor epitaxial material of a different composition is used, and the slope of the first-first conductivity-type semiconductor layer may be different.

For example, in a semiconductor light emitting device 150a that emits green or blue light, the angle (A3) between the lower surface and the side surface of the first-first conductivity-type semiconductor layer may be smaller than the angle (A4) between the lower surface and the side surface of the first-first conductivity-type semiconductor layer in a semiconductor light emitting device 150b that emits red light.

In addition, in a semiconductor light emitting device 150a that emits green or blue light, the angle (B3) between the upper surface and the side surface of the first-first conductivity-type semiconductor layer may be larger than the angle (B4) between the upper surface and the side surface of the first-first conductivity-type semiconductor layer in a semiconductor light emitting device 150b that emits red light.

On the other hand, even if the semiconductor light emitting device 150 is a semiconductor light emitting device 150a that emits green or blue light, or a semiconductor light emitting device 150b that emits red light, the length of the upper surface of the first-first conductivity-type semiconductor layer may be the same. Accordingly, in the fourth embodiment, the distance (D6) between the chip and the barrier wall 120 may be constant regardless of the semiconductor epitaxial material of the semiconductor light emitting device 150.

Therefore, the fourth embodiment has a special technical effect in that the distance between the chip and the barrier wall is maintained constant even if the colors emitted by the semiconductor light emitting device are different, thereby preventing defective assembly such as color mixing of RGB colors or double assembly.

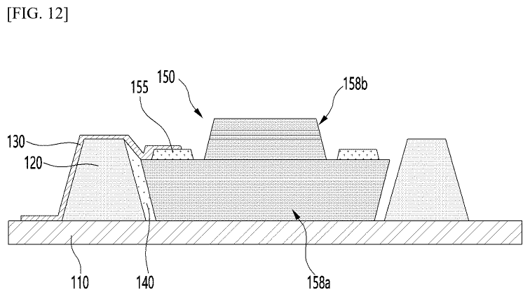

FIG. 12 is a conceptual diagram of a display device including a semiconductor light emitting device according to a fifth embodiment. FIG. 12 may employ technical features of the first to fourth embodiments. Referring to FIG. 12, the fifth embodiment may include a substrate 110, a semiconductor light emitting device 150, a barrier wall 120, an insulating layer 140, a contact electrode 130, and at least one electrode 155.

In this case, the first-first conductivity-type semiconductor layer 158a of the semiconductor light emitting device 150 may have a side surface facing the barrier wall 120 that is inclined in the same direction with respect to the vertical direction of the barrier wall 120. In addition, the first-first conductivity-type semiconductor layer 158a may have a side surface facing the barrier wall 120 that corresponds to the slope of the side surface.

Accordingly, regardless of the height of the first-first conductivity-type semiconductor layer 158a, a predetermined gap may be maintained between the barrier wall 120. In addition, the distance between the lower end of the first-first conductivity-type semiconductor layer 158a and the barrier wall 120 may correspond to the distance between the upper end of the first-first conductivity-type semiconductor layer 158a and the barrier wall 120.

Accordingly, in the fifth embodiment, the gap between the semiconductor light emitting device 150 and the barrier wall 120 may be filled uniformly with the insulating layer 140. In addition, the distance between the barrier wall 120 and the electrode 155 may be shortened. In addition, even if the slope of the first-first conductivity-type semiconductor layer 158a is different depending on the color emitted by the semiconductor light emitting device 150, the barrier wall 120 and the electrode 155 may be disposed closely together.

Accordingly, the fifth embodiment has a special technical effect in that when the contact electrode 130 is connected to the electrode 155 along the barrier wall 120 and the insulating layer 140, the contact process becomes easier and the reliability of the contact electrode 130 is improved.

Furthermore, since the semiconductor light emitting device 150 of the fifth embodiment has a heterogeneous slope, the upper surface of the first-first conductivity-type semiconductor layer 158a is longer than the lower surface, thereby securing a larger area of electrodes for electrical contact. This has the technical effect of improving process errors in the contact electrode process.

While FIG. 12 illustrates the contact electrode 130 as being connected to only one electrode 155 of the semiconductor light emitting device 150, the same configuration may be applied to both electrodes.

The semiconductor light emitting device for pixels according to the embodiment and the display device including the same have the technical effect of improving the correct assembly rate during self-assembling.

For example, the embodiment can prevent defective assembly, such as double assembly or non-assembly, and improve the correct assembly rate by forming the slopes of the facing sides of the first-first conductivity-type semiconductor layer and the assembly barrier to correspond.

Furthermore, the embodiment has the technical effect of improving the degree of freedom in designing the size and position of electrodes for electrical connection with contact electrodes in a horizontal semiconductor light emitting device.

For example, the embodiment forms the light emitting structure and the first-first conductivity-type semiconductor layer to have different slopes, so that the upper surface of the first-first conductivity-type semiconductor layer is longer than the lower surface, thereby improving the degree of freedom in designing the size and position of electrodes positioned on the upper surface.

Furthermore, the embodiment has the technical effect of ensuring the ease of a contact electrode process for electrical connection with a semiconductor light emitting device and improving the reliability of the contact electrode.

For example, the embodiment can secure a sufficient area of the electrode by securing the upper surface area of the first-first conductivity-type semiconductor layer in a semiconductor light emitting device having a heterogeneous slope structure, improve the error in the contact electrode process, and enhance reliability.

In addition, the embodiment has the technical effect of improving the light distribution of the semiconductor light emitting device, thereby enhancing light efficiency.

In addition, the embodiment has the technical effect of improving the deviation according to the optical viewing angle by enhancing light extraction at the center of the semiconductor light emitting device.

For example, the embodiment can improve light distribution through a heterogeneous slope structure in a semiconductor light emitting device and enhance upward light extraction efficiency by disposing a reflective film on the side and bottom of a first-type conductivity-type semiconductor layer.

Furthermore, the embodiment has the technical effect of preventing defective assembly, such as color mixing or double assembly, by designing the gap between the chip and the barrier wall to be constant, regardless of the semiconductor epitaxial material constituting the semiconductor light emitting device.

For example, the embodiment can prevent color mixing and double assembly by maintaining the gap between the chip and the barrier wall correspondingly, even when the semiconductor epitaxial material constituting the semiconductor light emitting device is different, thereby preventing a decrease in assembly rate.

### EXPLANATION OF CITED REFERENCE

10, 110: Substrate
20, 120: Barrier
30, 130: Contact electrode
40, 140: Insulating layer
150: Semiconductor light emitting device
151: first-second conductivity-type semiconductor layer
151a: first conductivity-type semiconductor layer
152: Active layer
153: second conductivity-type semiconductor layer
155: Electrode
156: second electrode
158a: first-first conductivity-type semiconductor layer
158b: Light emitting structure
160H: Assembly hole
170: Reflective film
170a: First Semi-Desert
170b: Second Semi-Desert

### Industrial Applicability

The embodiments can be applied to display fields that display images or information.

The embodiments can be applied to display fields that display images or information using semiconductor light emitting devices.

The embodiments can be applied to display fields that display images or information using micro- or nano-scale semiconductor light emitting devices.

1. A semiconductor light emitting device for pixels comprising:
a first-first conductivity-type semiconductor layer;
a light emitting structure disposed on the first-first conductivity-type semiconductor layer, comprising a first-second conductivity-type semiconductor layer, an active layer, and a second conductivity-type semiconductor layer, and
at least one electrode disposed on the first-first conductivity-type semiconductor layer, and
wherein side surfaces of the first-first conductivity-type semiconductor layer and the light emitting structure have different inclination direction.

2. The semiconductor light emitting device for pixels according to claim 1, wherein a slope of the side surface of the first-first conductivity-type semiconductor layer and a slope of the side surface of the light emitting structure have a positive (+) slope and a negative (−) slope, respectively, based on an upper surface of the first-first conductive semiconductor layer.

3. The semiconductor light emitting device for pixels according to claim 1, wherein an angle between a lower surface and the side surface of the first-first conductive semiconductor layer is an obtuse angle, and an angle between an upper surface and the side surface of the first-first conductive semiconductor layer is an acute angle.

4. The semiconductor light emitting device for pixels according to claim 1, wherein a length of an upper surface of the first-first conductivity-type semiconductor layer is longer than a length of a lower surface.

5. The semiconductor light emitting device for pixels according to claim 1, further comprising a reflective film disposed on the side surface or a bottom surface of the first-first conductivity-type semiconductor layer.

6. The semiconductor light emitting device for pixels according to claim 1, wherein the light emitting structure is disposed to one side with respect to a center of the first-first conductivity-type semiconductor layer.

7. A display device including a semiconductor light emitting device for pixels comprising:
a substrate;
an assembly barrier wall disposed on the substrate and having an assembly hole, and
a semiconductor light emitting device disposed within the assembly hole,
wherein the semiconductor light emitting device comprises a first-first conductivity-type semiconductor layer;
a light emitting structure disposed on the first-first conductivity-type semiconductor layer, comprising a first-second conductivity-type semiconductor layer, an active layer, and a second conductivity-type semiconductor layer, and
at least one electrode disposed on the first-first conductivity-type semiconductor layer, and
wherein side surfaces of the first-first conductivity-type semiconductor layer and the light emitting structure have different inclination direction.

8. The display device having the semiconductor light emitting device for pixels according to claim 7, wherein opposing sides of the first-first conductivity-type semiconductor layer and the assembly barrier wall comprise corresponding slopes.

9. The display device having the semiconductor light emitting device for pixels according to claim 7, wherein a distance between a top end of the first-first conductivity-type semiconductor layer and a lower end of the assembly barrier wall are configured to correspond to the lower end of the first-first conductivity-type semiconductor layer and the assembly barrier wall.

10. The display device having the semiconductor light emitting device for pixels according to claim 8, wherein the opposing sides of the first-first conductivity-type semiconductor layer and the assembly barrier wall comprise parallel slopes.

11. The display device having the semiconductor light emitting device for pixels according to claim 9, wherein the distance between the top end of the first-first conductivity-type semiconductor layer and the lower end of the assembly barrier wall is equal to the distance between a lower end of the first-first conductivity-type semiconductor layer and the assembly barrier wall.

12. The display device having the semiconductor light emitting device for pixels according to claim 7, further comprising an insulating layer disposed between the barrier wall and the semiconductor light emitting device, and
wherein a slope of an upper surface of the insulating layer is constant.

13. The display device having the semiconductor light emitting device for pixels according to claim 7, wherein a distance between the first-first conductive semiconductor layer and the barrier wall is configured to increases from a top to a bottom of the first-first conductive semiconductor layer.

14. The display device having the semiconductor light emitting device for pixels according to claim 10, wherein a distance between the side surface of the first-first conductive semiconductor layer and the assembly barrier is constant along the vertical direction.

15. The display device having the semiconductor light emitting device for pixels according to claim 7, wherein a diameter of a lower surface of the assembly hole is smaller than a maximum width of the semiconductor light emitting device.

16. The semiconductor light emitting device for pixels according to claim 7, wherein a slope of the side surface of the first-first conductivity-type semiconductor layer and a slope of the side surface of the light emitting structure have a positive (+) slope and a negative (−) slope, respectively, based on an upper surface of the first-first conductive semiconductor layer.

17. The semiconductor light emitting device for pixels according to claim 7, wherein an angle between a lower surface and the side surface of the first-first conductive semiconductor layer is an obtuse angle, and an angle between an upper surface and the side surface of the first-first conductive semiconductor layer is an acute angle.

18. The semiconductor light emitting device for pixels according to claim 7, wherein a length of an upper surface of the first-first conductivity-type semiconductor layer is longer than a length of a lower surface.

19. The semiconductor light emitting device for pixels according to claim 7, further comprising a reflective film disposed on the side surface or a bottom surface of the first-first conductivity-type semiconductor layer.

20. The semiconductor light emitting device for pixels according to claim 7, wherein the light emitting structure is disposed to one side with respect to a center of the first-first conductivity-type semiconductor layer.
